(19) United States
(12) Patent Application Publication
(10) Pub. No.: US 2020/0119173 A1
(43) Pub. Date: Apr. 16, 2020

(54) ADVANCED FIELD STOP THYRISTOR STRUCTURE AND MANUFACTURE METHODS

(71) Applicant: Littelfuse Semiconductor (Wuxi) Co., Ltd., Wuxi (CN)

(72) Inventors: Ader Shen, Wuxi (CN); Huan Zhang, Wuxi (CN); Dongliang Li, Wuxi (CN); Jifeng Zhou, Wuxi (CN)

(73) Assignee: Littelfuse Semiconductor (Wuxi) Co., Ltd., Wuxi (CN)

(21) Appl. No.: 16/603,674

(22) PCT Filed: Apr. 24, 2017
(86) PCT No.: PCT/CN2017/081643

§ 371 Date: Oct. 8, 2019

(51) Int. Cl. H01L 29/74; H01L 29/66; H01L 29/10

(52) U.S. Cl. CPC H01L 29/74; H01L 29/1033; H01L 29/66363

(57) ABSTRACT

A power switching device may include a semiconductor substrate and a body region comprising an n-type dopant, the body region disposed in an inner portion of the semiconductor substrate; a first base layer disposed adjacent a first surface of the semiconductor substrate, the first p-base layer comprising a p-type dopant; a second base layer disposed adjacent a second surface of the semiconductor substrate, the second base layer comprising a p-type dopant; a first emitter region, disposed adjacent the first surface of the semiconductor substrate, the first emitter region comprising a n-type dopant; a second emitter-region, disposed adjacent the second surface of the semiconductor substrate, the second emitter-region comprising a n-type dopant; a first field stop layer arranged between the first base layer and the body region, the first field stop layer comprising a n-type dopant; and a second field stop layer arranged between the second base layer and the body region, the second field stop layer comprising a n-type dopant.

### BACKGROUND

### Field

Embodiments relate to the field of power switching devices, and more particularly to semiconductor devices for power switching and control application.

### Discussion of Related Art

Semiconductor devices are widely used in control of electric power, ranging from light dimmers electric motor speed control to high-voltage direct current power transmission. A thyristor is a device based upon four different semiconductor layers arranged in electrical series and generally formed within a monocrystalline substrate such as silicon. In particular, a thyristor includes four layers of alternating N-type and P-type materials arranged between an anode and cathode. For high voltage applications where a blocking voltage of thousands of volts may be required, thyristors are fabricated in relatively thicker substrates to accommodate the electric field across the substrate. A thicker wafer also entails a higher on state voltage as well as greater power consumption, and a longer turn on time, in the thyristor device.

It is with respect to these and other issues the present disclosure is provided.

### SUMMARY

In one embodiment, a power switching device may include a semiconductor substrate, and a body region comprising an n-type dopant, the body region disposed in an inner portion of the semiconductor substrate. The power switching device may further include a first base layer, disposed adjacent a first surface of the semiconductor substrate, the first base layer comprising a p-type dopant, and a second base layer, disposed adjacent a second surface of the semiconductor substrate, the second base layer comprising a p-type dopant. The power switching device may also include a first emitter region, disposed adjacent the first surface of the semiconductor substrate, the first emitter region comprising a n-type dopant, and a second emitter-region, disposed adjacent the second surface of the semiconductor substrate, the second emitter-region comprising a n-type dopant. The power switching device may additionally include a first field stop layer, arranged between the first base layer and the body region, the first field stop layer comprising a n-type dopant, and a second field stop layer, arranged between the second base layer and the body region, the second field stop layer comprising a n-type dopant.

In an additional embodiment, a method of forming a power switching device, may include providing a semiconductor substrate, the semiconductor substrate comprising an n-dopant having a first concentration. The method may further include forming a first field stop layer extending from a first surface of the semiconductor substrate and a second field stop layer extending from a second surface of the semiconductor substrate, opposite the first surface, wherein the first field stop layer and the second field stop layer comprising an n-dopant having a second concentration, where the second concentration is greater than the first concentration. The method may include forming a first base layer within a portion of the first field stop layer and a second base layer in a portion of the second field stop layer, wherein the first base layer and the second base layer comprise a p-dopant. The method may also include forming a first emitter region within a portion of the first base layer and a second emitter region within a portion of the second base layer, wherein the first emitter region and the second emitter region comprise an n- dopant having a third concentration, the third concentration being greater than the second concentration.

### BRIEF DESCRIPTION OF THE DRAWINGS

FIG. 1A presents a side cross-sectional view of a power switching power switching device according to various embodiments of the disclosure;

FIG. 1B presents an electric field diagram consistent with the embodiment of FIG. 1A;

FIG. 2A presents dopant profile and electric field profile for a power switching power switching device according to embodiments of the disclosure;

FIG. 2B presents a voltage profile corresponding to the electric field profile of FIG. 2A;

FIGS. 3A to 3E present a side cross-sectional depiction of various stages of formation of a power switching power switching device according to further embodiments of the disclosure;

FIG. 4A presents a side cross-sectional view of a power switching power switching device according to other embodiments of the disclosure;

FIG. 4B presents an electric field diagram consistent with the embodiment of FIG. 4A;

FIG. 5A presents dopant profile and electric field profile for a power switching power switching device according to embodiments of the disclosure; and

FIG. 5B presents a voltage profile corresponding to the electric field profile of FIG. 5A.

### DESCRIPTION OF EMBODIMENTS

The present embodiments will now be described more fully hereinafter with reference to the accompanying drawings, in which various embodiments are shown. The embodiments may be embodied in many different forms and are not to be construed as limited to the embodiments set forth herein. These embodiments are provided so that this disclosure will be thorough and complete, and will fully convey the scope of the embodiments to those skilled in the art. In the drawings, like numbers refer to like elements throughout.

In the following description and/or claims, the terms “on,” “overlying,” “disposed on” and “over” may be used in the following description and claims. “On,” “overlying,” “disposed on” and “over” may be used to indicate when two or more elements are in direct physical contact with one another. The terms “on,”, “overlying,” “disposed on,” and over, may also mean when two or more elements are not in direct contact with one another. For example, “over” may mean when one element is above another element and not in contact with another element, and may have another element or elements in between the two elements. Furthermore, the term “and/or” may mean “and”, it may mean “or”, it may mean “exclusive-or”, may mean “one”, may mean “some, not all”, may mean “neither”, and/or it may mean “both.” The scope of claimed subject matter is not limited in this respect.

The present embodiments are generally related to power switching power switching devices, and in particular, to thyristor type devices. Examples of thyristor type devices include SCRs, TRIACs. For high voltage applications, the present embodiments provide improved configurations where higher voltage may be accommodated in a relatively thinner substrate as compared to conventional thyristors.

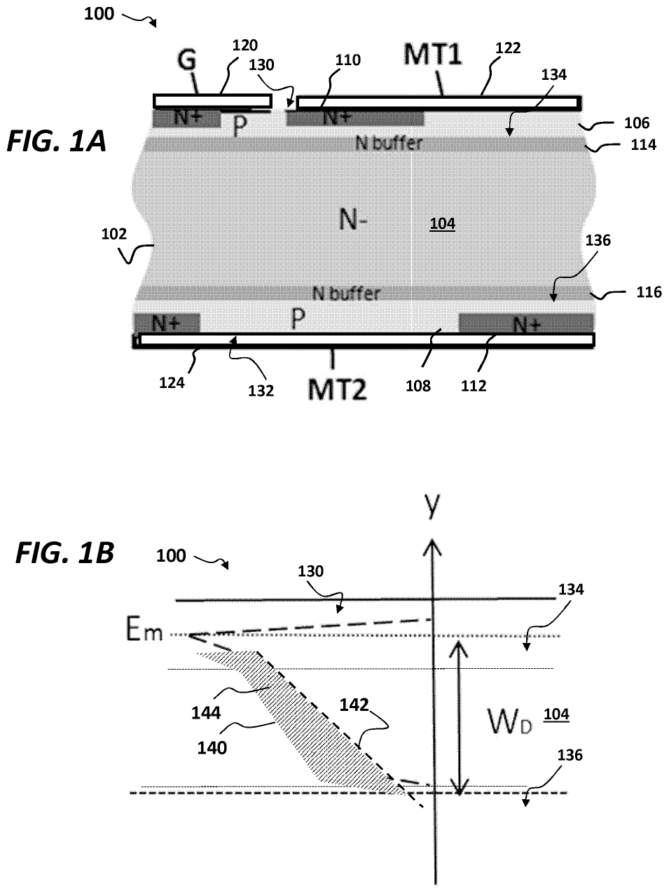

FIG. 1A presents a side cross-sectional view of a power switching power switching device 100 according to various embodiments of the disclosure. The power switching device 100 is formed in a semiconductor substrate 102, such as a silicon substrate. The power switching device 100 may include a body region 104, comprising an n-type dopant, where the body region 104 is disposed in an inner portion of the semiconductor substrate 102. The body region 104 may be formed by doping a monocrystalline substrate according to any convenient known method. Without limitation, in various embodiment the body region 104 has a dopant concentration less than 2.0×10¹⁴ cm⁻³.

As shown in FIG. 1A, the power switching device 100 may also include a first base layer 106, disposed adjacent a first surface 130 of the semiconductor substrate 102, and a second base layer 108, disposed adjacent a second surface 132 of the semiconductor substrate 102. The first base layer 106 and the second base layer 108 may comprise a p-type dopant. Without limitation, the first base layer 106 and the second base layer 108 may comprise a dopant concentration of 1.0×10¹⁶ cm⁻³ to 1.0×10¹⁸ cm⁻³.

The power switching device 100 may also include a first emitter region 110, disposed adjacent the first surface 130 of the semiconductor substrate 102, and a second emitter- region 112, disposed adjacent the second surface 132 of the semiconductor substrate 102. The first emitter region 110 and second emitter region 112 may comprises a n-type dopant. Without limitation, the first emitter region 110 and the second emitter region 112 may comprise a dopant concentration of between 1.0×10¹⁸ cm⁻³ to 1.0×10²⁰ cm⁻³.

The power switching device 100 may further include a gate contact 120, disposed on the first base region 106, a first terminal contact 122 (shown as MT1), disposed on the first emitter region 110, and electrically isolated from the gate contact 120. The power switching device 100 may also include a second terminal contact 124 (shown as MT2), disposed on the second emitter region 112.

As such, the power switching device 100 may function as a thyristor, according to known principles. To support high voltage operation, the thickness of the substrate 102 may be designed to accommodate the high electric fields accompanying high blocking voltage. Advantageously, the power switching device 100 further includes a first field stop layer 114, arranged between the first base layer 106 and the body region 104, and a second field stop layer 116, arranged between the second base layer 108 and the body region 104. The first field stop layer 114 and second field stop layer 116 may comprise a n-type dopant; wherein the first field stop layer 114 and the second field stop layer 116 have a dopant concentration of 1.0×10¹³ cm ⁻³ to 1.0×10¹⁷ cm⁻³. The embodiments are not limited in this context.

By providing the first field stop layer 114 and the second field stop layer 116, the power switching device 100 may support a relatively higher blocking voltage, while constructed with a relatively lesser thickness, as compared to known high voltage thyristors. The advantages provided by the power switching device 100 may be better understood with reference to FIG. 1B, presenting a rough electric field diagram consistent with the embodiment of FIG. 1A. As illustrated in FIG. 1B, when a voltage is applied across the power switching device 100, an electric field as shown by curve 140 may develop between the first surface 130 and the interface 136, which interface represents the P/N junction formed between the second base layer 108 and second field stop layer 116. The magnitude of the electric field peaks at the P/N junction defined between first field stop layer 114 and first base layer 106. Because the first field stop layer 114 may have a higher dopant concentration that the body region 104, the magnitude of the electric field may decrease relatively rapidly with depth (along the Y-direction, perpendicular to the first surface 130) across the thickness of the first field stop layer 114. The electric field then changes gradually across the body region 104, again changing more rapidly across the second field stop layer 116. The electric field distribution across the substrate 102 accordingly in better optimized to support a higher voltage as compared to a known thyristor lacking the first field stop layer 114 and second field stop layer 116. For comparison, the curve 142 suggests the electric field distribution for a reference thyristor when no field stop layers are present. In particular, the blocking voltage of a device may be defined as an area under the electric field distribution across a substrate, as schematically represented by an area defined by curve 140, or by curve 142. By using field stop layers, the change in electric field across the body region 104 may be more gradual, leading to a larger area of the electric field distribution for curve 140, as compared to curve 142, and shown by the extra area 144. Accordingly, for the same substrate thickness, the total area under the curve 140 is much larger than the area under the curve 142, meaning that the blocking voltage is much larger using the field stop design of the present embodiments. Said differently, in order to generate the same area under the curve for electric field distribution, and thus achieve a similar blocking voltage while not having the field stop layers of the present embodiments, a substrate thickness would need to be much larger.

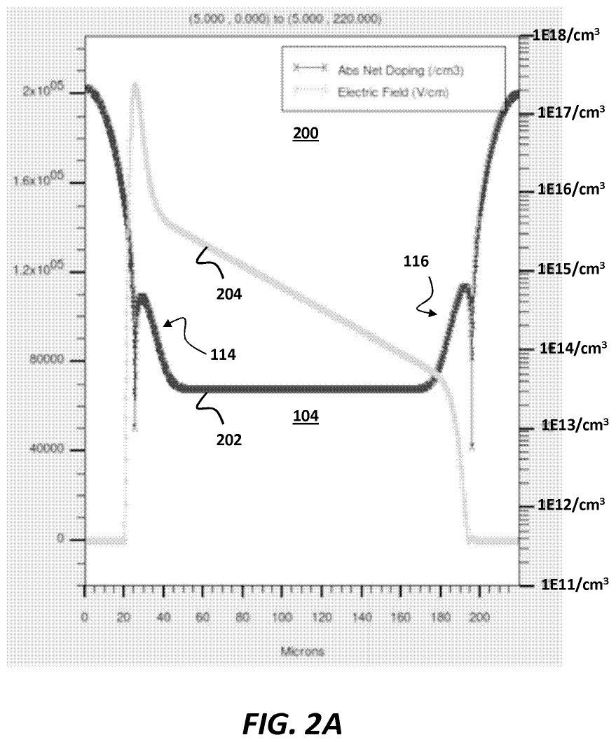

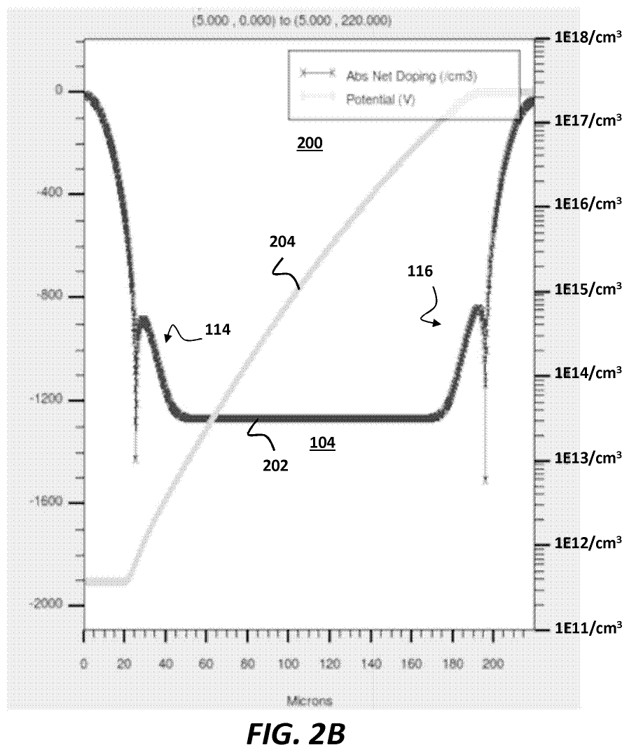

FIG. 2A presents dopant profile and electric field profile for a power switching device 200 according to embodiments of the disclosure, while FIG. 2B presents a voltage profile corresponding to the electric field profile of FIG. 2A. In particular, in FIG. 2A, a curve 202 is shown, representing the net dopant concentration as a function of depth in a 240 micrometer thick substrate. The curve 202 is a simulation based upon formation of a base region adjacent opposite surfaces of a substrate, with buried field stop regions, corresponding to the first field stop layer 114, and second field stop layer 116, discussed above. As illustrated, the relative dopant concentration is lowest in the body region 104. As further shown by a curve 204, representing the electric field associated with a voltage applied across the power switching device 200, the magnitude of the electric field peaks at a value of 2×10⁵ V/cm value at the P/N junction, adjacent to the first field stop layer 114. The magnitude of the electric field rapidly drops across the first field stop layer 114 to 1.4×10⁵ V/cm, followed by a more gradual drop across the body region 104, to a value of 8×10⁴ V/cm. The electric field then drops to zero across the second field stop layer 116.

Turning now to FIG. 2B, a corresponding voltage behavior is shown, represented by curve 204. In this example, a voltage of —1900 V is maintained at the left side of the power switching device 200. The magnitude of the voltage decreases across the n-doped regions of the substrate, including the first field stop layer 114, the body region 104, and the second field stop layer 116, reaching zero near the P/N junction defined to the right of the second field stop layer 116.

Notably, electric field and voltage simulations were also carried out where a similar dopant profile as curve 202 was applied across a substrate, except no field stop layers were provided. Such simulations were characteristic of known thyristors without the field stop layers. The results show that for a similar 1900 V drop across the substrate, a substrate thickness of approximately 280 micrometers to 290 micrometers is needed to properly accommodate the electric field and voltage change.

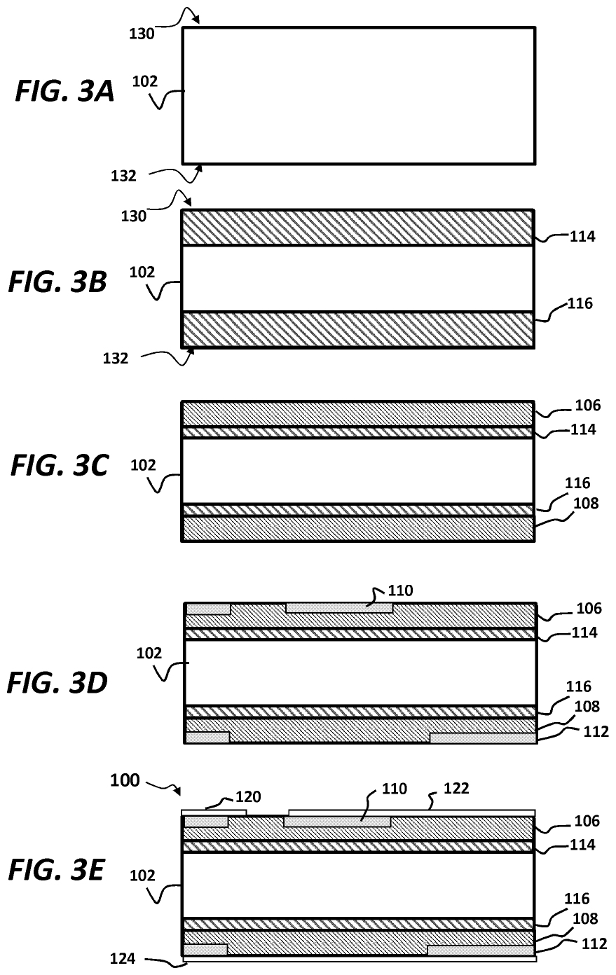

FIG. 3A to FIG. 3E present a side cross-sectional depiction of various stages of formation of a power switching device according to further embodiments of the disclosure. In FIG. 3A, a semiconductor substrate 102 is provided. In various embodiments, the semiconductor substrate 102 may be monocrystalline silicon that is doped with an n dopant, having a dopant concentration less than 2.0×10¹⁴ cm⁻³. Depending upon the designed blocking voltage for a device to be fabricated, the thickness of the semiconductor substrate 102 may be adjusted.

At FIG. 3B, a first field stop layer 114 and a second field stop layer 116 are formed on opposite sides of the semiconductor substrate 102. As illustrated, the first field stop layer 114 extends from the first surface 130, while the second field stop layer 116 extends from the second surface 132. In various embodiments, the first field stop layer 114 and the second field stop layer 116 may comprise an n dopant having a dopant concentration greater than the dopant concentration of the substrate 102. In some embodiments, the dopant concentration may be between 1.0×10¹³ cm⁻³ to 1.0×10¹⁷ cm−³. The field stop layers may be formed according to different methods. In one example, the doping to form the first field stop layer 114 and the second field stop layer 116 may be performed by implanting the surface region of the semiconductor substrate 102, on opposite sides. For example, in one approach, implantation may be performed to implant n dopants within a few micrometers or so of the first surface 130 and of the second surface 132. This surface region implantation may be followed by a high temperature drive in anneal that drives the dopants to a target depth below the respective surfaces, such as 40 micrometers. In another approach, a high energy implant process may be performed (such as energies up to or greater than 1 MeV) to implant an n-doped layer and directly form the first field stop layer 114 and second field stop layer 116, while not needing a subsequent drive in anneal.

Referring back to FIG. 3A, in an alternative embodiment, an epitaxial N-doped layer may be grown to a designed thickness on the first surface 130 and on the second surface 132, to form the first field stop layer 114 and the second field stop layer 116. The first thickness of the first field stop layer 114 and the second thickness of the second field stop layer 116 may be in a range of 10 micrometers to 20 micrometers.

Turning now to FIG. 3C, there is shown the further operations of forming a first base layer 106 within a portion of the first field stop layer 114, and forming a second base layer 108 in a portion of the second field stop layer 116. In this operation, the first base layer 106 and second base layer 108 are doped with a p dopant, wherein the first base layer 106 and the second base layer 108 comprise a p-dopant. In some embodiments, the first base layer 106 and the second base layer 108 comprise a dopant concentration of 1.0×10¹⁶ cm⁻³ to 1.0×10¹⁸ cm⁻³. As shown in FIG. 3C, the first base layer 106 and the second base layer 108 extend from the first surface 130 and the second surface 132, so as to be formed within an outer portion of the first field stop layer 114 and second field stop layer 116, respectively. The doping level of p dopant is such that the outer portions have a net p-dopant concentration, forming the first base layer 106 and second base layer 108. As a consequence, in some embodiments, the first field stop layer 114 may be disposed between 10 micrometers and 40 micrometers from the first surface 130 and the second field stop layer may be disposed between 10 micrometers and 40 micrometers from the second surface 132.

Turning now to FIG. 3D, there is shown a subsequent operation of forming a first emitter region 110 within a portion of the first base layer 106 and a second emitter region 112 within a portion of the second base layer 108, where the first emitter region 110 and the second emitter region 112 comprise an n-dopant. In various embodiments, the first emitter region 110 and the second emitter region 112 may comprise a dopant concentration of between 1.0×10¹⁸ cm⁻³ to 1.0×10²⁰ cm⁻³. Again, the net concentration of dopants is such that the regions where the first emitter region 110 and second emitter region 112 are formed have an excess of n dopants, even if located in the base layers.

In FIG. 3E, metal contacts are formed, so as to form contacts to act as gate electrode, first terminal electrode (anode) and second terminal electrode (cathode), to complete formation of a power switching device. In comparison to known thyristor devices, the power switching device thus formed may have a thinner substrate, a lower ON state voltage drop, a higher ON state current rating. Moreover, the base layers may be substantially shorter and allow carriers to drift through the base layers more rapidly for quicker turn on. For thyristors having isolation structures, the use of thinner substrates also reduces the thermal budget needed for fabrication of the various layers.

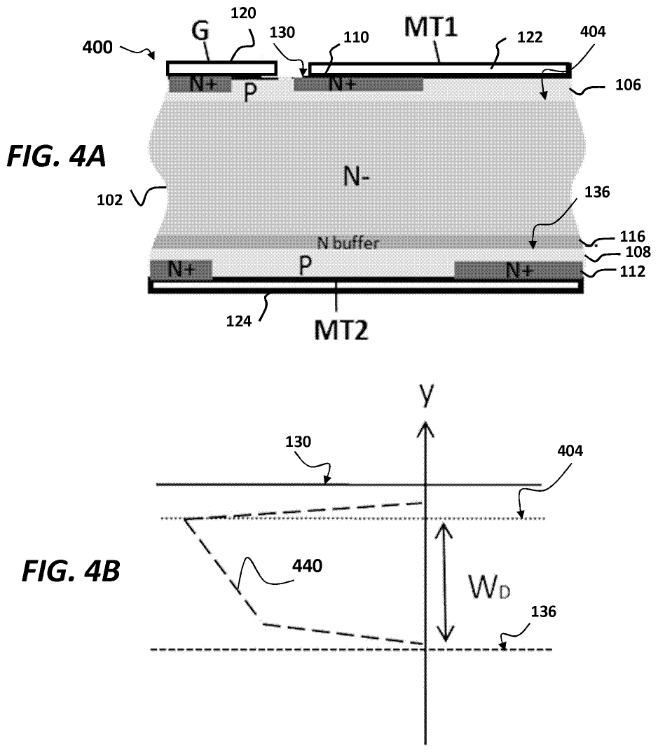

Turning now to FIG. 4A there is shown a side cross-sectional view of a power switching device 400 according to other embodiments of the disclosure. FIG. 4B presents an electric field diagram consistent with the embodiment of FIG. 4A. In FIG. 4A the power switching device 400 may be similar to the power switching device 100, save for the fact that just one field stop layer, second field stop layer 116, is included. As shown in FIG. 4B, the electric field 440, shows slightly different distribution. While the magnitude peaks at the interface 404, corresponding to a P/N junction, a rapid decrease in electric field magnitude takes place through the second field stop layer 116, as shown.

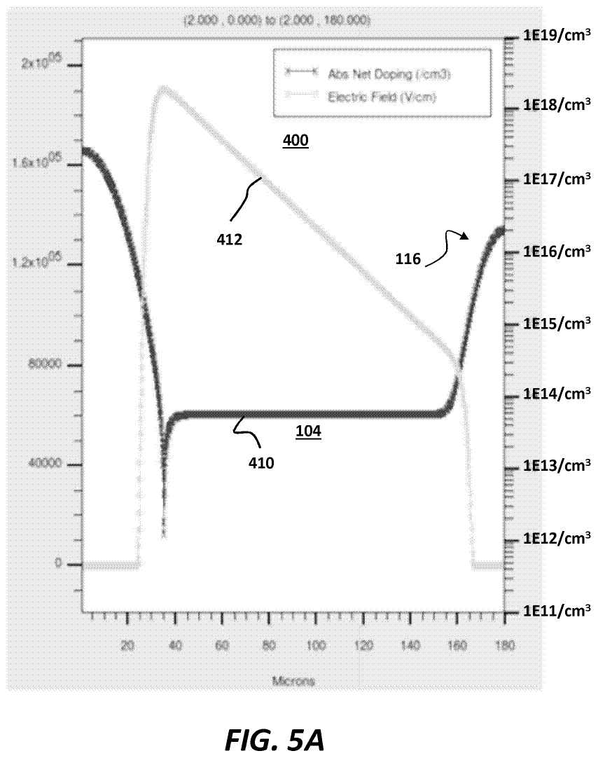

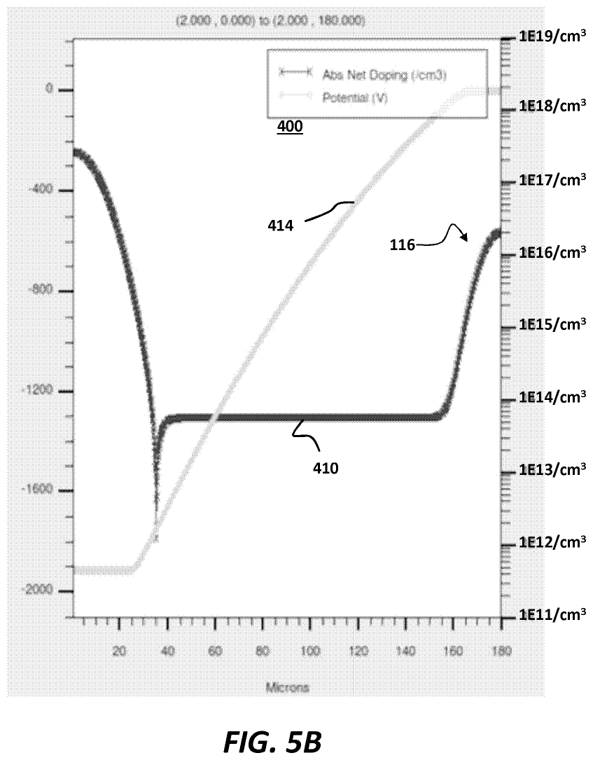

FIG. 5A presents a dopant profile and electric field profile for the power switching device 400 according to embodiments of the disclosure, and FIG. 5B presents a voltage profile corresponding to the electric field profile of FIG. 5A. In this example, the simulation is generally the same as described above with respect to FIGS. 2A and 2B, while just one field stop layer is present. The curve 410 represents the dopant profile, while the curve 412 represents the electric field, and the curve 414 represents voltage across the substrate. In the figures, the profile is just shown down to 180 micrometers below the surface, while the second base region is not shown. Again, a large portion of the electric field drop takes place across the second field stop layer 116.

While the present embodiments have been disclosed with reference to certain embodiments, numerous modifications, alterations and changes to the described embodiments are possible without departing from the sphere and scope of the present disclosure, as defined in the appended claims. Accordingly, the present embodiments may not be limited to the described embodiments, but have the full scope defined by the language of the following claims, and equivalents thereof.

What is claimed is:

1. A power switching device, comprising:
a semiconductor substrate;
a body region comprising an n-type dopant, the body region disposed in an inner portion of the semiconductor substrate;
a first base layer, disposed adjacent a first surface of the semiconductor substrate, the first base layer comprising a p-type dopant;
a second base layer, disposed adjacent a second surface of the semiconductor substrate, the second base layer comprising a p-type dopant;
a first emitter region, disposed adjacent the first surface of the semiconductor substrate, the first emitter region comprising a n-type dopant;
a second emitter region, disposed adjacent the second surface of the semiconductor substrate, the second emitter-region comprising a n-type dopant;
a first field stop layer, arranged between the first base layer and the body region, the first field stop layer comprising a n-type dopant; and
a second field stop layer, arranged between the second base layer and the body region, the second field stop layer comprising a n-type dopant.

2. The power switching device of claim 1, wherein at least a portion of the first base layer is disposed between the first emitter region and the first field stop layer, and wherein at least a portion of the second base layer is disposed between the second emitter region and the second field stop layer.

3. The power switching device of claim 1, further comprising:
a gate contact, disposed on the first base layer;
a first terminal contact, disposed on the first emitter region, and electrically isolated from the gate contact; and
a second terminal contact, disposed on the second emitter region.

4. The power switching device of claim 1, wherein the first field stop layer comprises a first thickness, wherein the second field stop layer comprises a second thickness, wherein the first thickness and the second thickness are in a range of 10 micrometers to 20 micrometers.

5. The power switching device of claim 1, wherein the first field stop layer is disposed between 10 micrometers and 40 micrometers from the first surface, and wherein the second field stop layer is disposed between 10 micrometers and 40 micrometers from the second surface.

6. The power switching device of claim 1, wherein the body region comprises a having a dopant concentration less than 2.0×10¹⁴ cm⁻³.

7. The power switching device of claim 1, wherein the first base layer and the second base layer comprise a dopant concentration of 1.0×10¹⁶ cm⁻³ to 1.0×10¹⁸ cm⁻³.

8. The power switching device of claim 1, wherein the first field stop layer and the second field stop layer comprise a dopant concentration of 1.0×10¹³ cm⁻³ to 1.0×10¹⁷ cm⁻³.

9. The power switching device of claim 1, wherein the first emitter region and the second emitter region comprise a dopant concentration of between 1.0×10¹⁸ cm⁻³ to 1.0×10²⁰ cm⁻³.

10. A method of forming a power switching device, comprising:
providing a semiconductor substrate, the semiconductor substrate comprising an n-dopant having a first concentration;
forming a first field stop layer extending from a first surface of the semiconductor substrate and a second field stop layer extending from a second surface of the semiconductor substrate, opposite the first surface, wherein the first field stop layer and the second field stop layer comprising an n-dopant having a second concentration, the second concentration being greater than the first concentration;
forming a first base layer within a portion of the first field stop layer and a second base layer in a portion of the second field stop layer, wherein the first base layer and the second base layer comprise a p-dopant; and
forming a first emitter region within a portion of the first base layer and a second emitter region within a portion of the second base layer, wherein the first emitter region and the second emitter region comprise an n-dopant having a third concentration, the third concentration being greater than the second concentration.

11. The method of claim 10, wherein the first field stop layer and the second field stop layer are separated by a body region, the body region comprising the n-dopant having the first concentration.

12. The method of claim 10, wherein the first concentration is less than 2.0×10¹⁴ cm⁻³.

13. The method of claim 10, wherein the first base layer and the second base layer comprise a dopant concentration of 1.0×10¹⁶ cm⁻³ to 1.0×10¹⁸ cm⁻³.

14. The method of claim 10, wherein the first field stop layer and the second field stop layer comprise a dopant concentration of 1.0×10¹³ cm⁻³ to 1.0×10¹⁷ cm⁻³.

15. The method of claim 10, wherein the first and the second comprise a dopant concentration of between 1.0×10¹⁸ cm⁻³ to 1.0×10²⁰ cm⁻³.

16. The method of claim 10, wherein the forming the first field stop layer and the second field stop layer comprise one of:
implanting an n dopant in a surface region of the substrate and annealing the substrate to perform a drive in of the n dopant;
growing a first N-doped layer on a first side of the semiconductor substrate and a second N-doped layer on a second side of the semiconductor substrate; and
performing a high energy implant of n dopant, wherein an implant energy is greater than 1 MeV.

17. The method of claim 10, wherein the first field stop layer is disposed between 10 micrometers and 40 micrometers from the first surface, and wherein the second field stop layer is disposed between 10 micrometers and 40 micrometers from the second surface.
